(19) United States
(12) Patent Application Publication
(10) Pub. No.: US 2025/0379581 A1
(43) Pub. Date: Dec. 11, 2025

(54) LEVEL SHIFTER AND MEMORY DEVICE INCLUDING THE SAME

(71) Applicant: Samsung Electronics Co., Ltd., Suwon-si (KR)

(72) Inventors: Donghee WON, Suwon-si (KR); Jongcheol KIM, Suwon-si (KR); Seongsoo PARK, Suwon-si (KR); Dongsu LEE, Suwon-si (KR)

(73) Assignee: Samsung Electronics Co., Ltd., Suwon-si (KR)

(21) Appl. No.: 19/016,725

(22) Filed: Jan. 10, 2025

(30) Foreign Application Priority Data
Jun. 11, 2024 (KR) 10-2024-0075819

(51) Int. Cl. H03K 19/0185; G11C 11/4093

(52) U.S. Cl. CPC H03K 19/018521; G11C 11/4093

(57) ABSTRACT

A level shifter includes a mid voltage output circuit configured to output a mid voltage based on an input voltage swinging between a first voltage level and a second voltage level, a feedback circuit configured to output a feedback voltage and an output voltage that swings between a positive target voltage level and a negative target voltage level based on a positive target voltage, a negative target voltage and the mid voltage, a pull-up voltage control circuit configured to output a first voltage or the positive target voltage to the mid voltage output circuit based on the feedback voltage, and a pull-down voltage control circuit configured to output at least one of a second voltage or the negative target voltage to the mid voltage output circuit based on the feedback voltage.

### CROSS-REFERENCE TO RELATED APPLICATION

This application is based on and claims priority under 35 U.S.C. § 119 to Korean Patent Application No. 10-2024-0075819, filed on Jun. 11, 2024, in the Korean Intellectual Property Office, the disclosure of which is incorporated by reference herein in its entirety.

### BACKGROUND

Some example embodiments relate to a level shifter, and more particularly, to a level shifter with improved performance.

Electronic devices may include a variety of components. Various components may operate in the same voltage domain or may operate in different voltage domains. Components belonging to the same voltage domain may operate using the same power supply voltage and the same ground voltage. Components belonging to different voltage domains may operate using different power supply voltages and different ground voltages.

To help ensure normal operation of components belonging to different voltage domains, level shifters may be used.

### SUMMARY

Some example embodiments provide a level shifter that outputs both positive and negative voltages as positive target voltage and negative target voltage through a single level shifter.

According to some example embodiments, there is provided a level shifter including a mid voltage output circuit configured to output a mid voltage based on an input voltage swinging between a first voltage level and a second voltage level, a feedback circuit configured to output a feedback voltage and an output voltage that swings between a positive target voltage level and a negative target voltage level, the outputting of the feedback circuit based on the positive target voltage, the negative target voltage, and the mid voltage, a pull-up voltage control circuit configured to output at least one of a first voltage or the positive target voltage to the mid voltage output circuit, the output of the pull-up voltage control circuit based on the feedback voltage, and a pull-down voltage control circuit configured to output at least one of a second voltage or the negative target voltage to the mid voltage output circuit, the output of the pull-down voltage control circuit based on the feedback voltage.

Alternatively or additionally according to some example embodiments, there is provided a level shifter including a first P-channel transistor having a gate terminal connected to an input voltage line, a source terminal connected to a first node, and a drain terminal connected to a second node, a first N-channel transistor having a gate terminal connected to the input voltage line, a source terminal connected to a third node, and a drain terminal connected to the second node, a second P-channel transistor having a gate terminal connected to a fourth node, a source terminal connected to a first voltage line, and a drain terminal connected to the first node, a third P-channel transistor having a gate terminal connected to a fifth node, a source terminal connected to a positive target voltage line, and a drain terminal connected to the first node, a second N-channel transistor having a gate terminal connected to the fourth node, a source terminal connected to a second voltage line, and a drain terminal connected to the third node, a third N-channel transistor having a gate terminal connected to the fifth node, a source terminal connected to a negative target voltage line, and a drain terminal connected to the third node, a fourth P-channel transistor having a gate terminal connected to the second node, a source terminal connected to a sixth node, and a drain terminal connected to the fifth node, a fourth N-channel transistor having a gate terminal connected to the second node, a source terminal connected to a seventh node, and a drain terminal connected to the fifth node, a fifth P-channel transistor having a gate terminal connected to the fifth node, a source terminal connected to the sixth node, and a drain terminal connected to the fourth node, a fifth N-channel transistor having a gate terminal connected to the fifth node, a source terminal connected to the seventh node, and a drain terminal connected to the fourth node, a sixth P-channel transistor having a gate terminal connected to the fourth node, a source terminal connected to the sixth node, and a drain terminal connected to an output voltage line, and a sixth N-channel transistor having a gate terminal connected to the fourth node, a source terminal connected to the seventh node, and a drain terminal connected to the output voltage line. The sixth node may be connected to the positive target voltage line, and the seventh node may be connected to the negative target voltage line.

Alternatively or additionally according to some example embodiments, there is provided a memory device including an input/output circuit configured to transmit and receive data, the input/output circuit including a level shifter, wherein the level shifter includes a mid voltage output circuit configured to output a mid voltage based on an input voltage swinging between a first voltage level and a second voltage level, a feedback circuit configured to output a feedback voltage and an output voltage that swings between a positive target voltage level and a negative target voltage level, the output of the feedback circuit based on the positive target voltage, the negative target voltage and the mid voltage, a pull-up voltage control circuit configured to output at least one of a first voltage or the positive target voltage to the mid voltage output circuit, the output of the pull-up voltage control circuit based on the feedback voltage, and a pull-down voltage control circuit configured to output at least one of a second voltage or the negative target voltage to the mid voltage output circuit, the output of the pull-down voltage control circuit based on the feedback voltage.

### BRIEF DESCRIPTION OF THE DRAWINGS

Some example embodiments will be more clearly understood from the following detailed description taken in conjunction with the accompanying drawings in which:

FIG. 1 is a diagram illustrating a level shifter according to some example embodiments;

FIG. 2 is a block diagram illustrating a level shifter according to some example embodiments;

FIG. 3 is a block diagram illustrating a mid voltage output circuit according to some example embodiments;

FIG. 4 is a diagram showing an equivalent circuit of a level shifter according to some example embodiments;

FIG. 5 is a diagram to explain the operation of a level shifter in a section (VSS->VNEG) according to some example embodiments;

FIG. 6 is a diagram to explain the operation of a level shifter in a section (VEXT->VPOS) according to some example embodiments;

FIG. 7 is a timing diagram to explain the operation of a level shifter in each of the sections (VSS->VNEG) and (VEXT->VPOS) according to some example embodiments;

FIG. 8 is a diagram illustrating a memory device including a level shifter according to some example embodiments;

FIG. 9 is a graph to explain a level shifter according to some example embodiments;

FIG. 10 is a block diagram of a computing system according to some example embodiments; and

FIG. 11 is a block diagram illustrating a system to which a storage device according to some example embodiments is applied.

### DETAILED DESCRIPTION OF SOME EXAMPLE EMBODIMENTS

Depending on the context, for example, the term “input voltage” to be described later may refer to “input signal” or “voltage level of input signal”, “mid voltage” to be described later may refer to “mid signal” or “voltage level of output signal”, and “output voltage” to be described later may refer to “output signal” or “voltage level of output signal”. For example, “voltage A” may refer to “signal A” or “voltage level of signal A” depending on the context.

Hereinafter, various example embodiments are described with reference to the accompanying drawings.

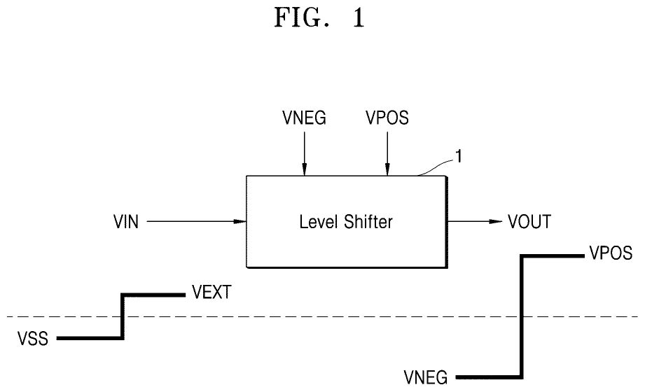

FIG. 1 is a diagram illustrating a level shifter according to some example embodiments.

A level shifter 1 of FIG. 1 may perform a compatible role by converting signals between two circuits using different voltage levels. For example, when a device using a 5 V logic level and a device using a 3.3 V logic level are to communicate with each other, the level shifter 1 may be implemented between the two devices. For example, through the level shifter 1, communication between devices using different voltage levels may be performed, compatibility of different devices with different reference values of logic levels may be secured or improved upon, and damage to devices due to different voltages may be prevented or reduced in likelihood of occurrence and/or in impact from occurrence.

The level shifter 1 according to some example embodiments may output an output signal swinging between target voltage levels based on a voltage level of an input signal swinging between different voltage levels.

Referring to FIG. 1, the level shifter 1 may output an output voltage VOUT that swings or steps between a positive target voltage VPOS level and a negative target voltage VNEG level based on an input voltage VIN that swings or steps between a first voltage VEXT level and a second voltage VSS level.

Here, the first voltage VEXT may be a positive voltage level, and the second voltage VSS may be a ground voltage level or a voltage close to the ground voltage. Referring to FIG. 1, the level of the positive target voltage VPOS may be higher than the level of the first voltage VEXT, and the level of the negative target voltage VNEG may be lower than the level of the second voltage VSS.

En some example embodiments, the positive target voltage VPOS level may be higher than the first voltage VEXT level, and the negative target voltage VNEG level may be lower than the second voltage VSS level, but example embodiments are not limited thereto. For example, in some example embodiments, the level of the positive target voltage VPOS may be lower than the level of the first voltage VEXT, and the level of the negative target voltage VNEG may be higher than the level of the second voltage VSS. Alternatively or additionally in some example embodiments, the level of the positive target voltage VPOS may be lower than the level of the first voltage VEXT, and the level of the negative target voltage VNEG may be lower than the level of the second voltage VSS. Alternatively or additionally in some example embodiments, the level of the positive target voltage VPOS may be higher than the level of the first voltage VEXT, and the level of the negative target voltage VNEG may be higher than the level of the second voltage VSS.

In some example embodiments, the level shifter 1 may receive a positive target voltage VPOS, a negative target voltage VNEG, and an input voltage VIN that swings or steps between the first voltage VEXT level and the second voltage VSS level, and may output an output voltage VOUT that swings or steps between the positive target voltage VPOS level and the negative target voltage VNEG level based on the input voltage VIN, the positive target voltage VPOS, and the negative target voltage VNEG.

In a latch-based level shifter according to a comparative example, a single latch-based level shifter may output only one voltage (one of a positive voltage and a negative voltage) as a target voltage (one of a corresponding positive target voltage and a corresponding negative target voltage) by having the single latch-based level shifter output a positive voltage as a positive target voltage or by having the single latch-based level shifter output a negative voltage as a negative target voltage. Accordingly, the design of both positive latch-based level shifter and negative latch-based level shifter can be considered when designing a semiconductor circuit, and thus, a silicon area cost for latch-based level shifters may be high.

Meanwhile, in the level shifter 1 according to some example embodiments, the single level shifter 1 outputs a positive voltage as a positive target voltage and a negative voltage as a negative target voltage, and thus, both positive and negative voltages may be output as a corresponding positive target voltage and a corresponding negative target voltage through the single level shifter 1. Accordingly, when a semiconductor circuit is designed, a silicon area cost for the level shifter may be reduced.

The level shifter 1 according to some example embodiments may output a positive voltage as a positive target voltage and a negative voltage as a negative target voltage without a leakage current path.

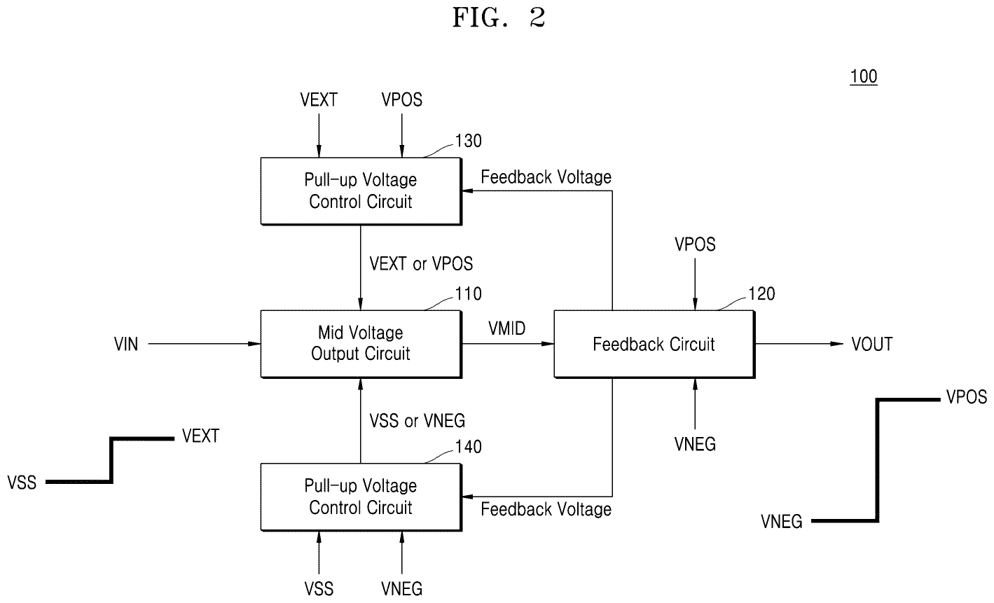

Hereinafter, an operation in which the single level shifter 1 outputs a positive voltage as a positive target voltage and a negative voltage as a negative target voltage is described in detail with reference to FIGS. 2 to 7.

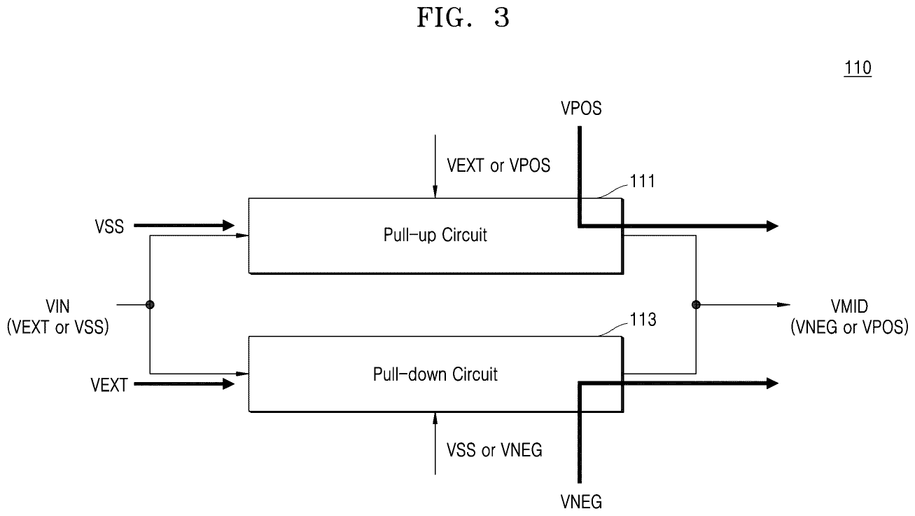

FIG. 2 is a block diagram illustrating a level shifter according to some example embodiments. FIG. 3 is a block diagram illustrating a mid voltage output circuit according to some example embodiments.

A level shifter 100 may include a mid voltage output circuit 110, a feedback circuit 120, a pull-up voltage control circuit 130, and a pull-down voltage control circuit 140.

The mid voltage output circuit 110 may receive an input signal swinging between or stepping between different voltage levels and may output a mid voltage VMID based on different voltage levels.

Referring to FIG. 2, the mid voltage output circuit 110 may output the mid voltage VMID to the feedback circuit 120 based on the input voltage VIN swinging between the first voltage VEXT level and the second voltage VSS level. Here, the mid voltage VMID may correspond to one of a positive target voltage VPOS and a negative target voltage VNEG according to the level of the input voltage VIN.

A detailed operation of the mid voltage output circuit 110 is described in detail with reference to FIG. 3.

The feedback circuit 120 may receive the positive target voltage VPOS, the negative target voltage VNEG, and the mid voltage VMID, and may output an output voltage VOUT that swings or steps between the positive target voltage VPOS level and the negative target voltage VNEG, with the outputting based on the positive target voltage VPOS, the negative target voltage VNEG, and the mid voltage VMID.

The feedback circuit 120 may output a feedback voltage based on the positive target voltage VPOS, the negative target voltage VNEG, and the mid voltage VMID.

Referring to FIG. 2, the feedback circuit 120 may output a feedback voltage to the pull-up voltage control circuit 130 and/or to the pull-down voltage control circuit 140.

Here, the feedback voltage may include the positive target voltage VPOS or the negative target voltage VNEG.

The pull-up voltage control circuit 130 may receive the first voltage VEXT, the positive target voltage VPOS, and the feedback voltage, and output the first voltage VEXT or the positive target voltage VPOS based on the feedback voltage.

Referring to FIG. 2, the pull-up voltage control circuit 130 may output the first voltage VEXT and/or the positive target voltage VPOS to the mid voltage output circuit 110 based on the feedback voltage.

For example, the pull-up voltage control circuit 130 may output the positive target voltage VPOS to the mid voltage output circuit 110 based on the feedback based on the input voltage VIN having the level of the second voltage VSS. In some example embodiments, the pull-up voltage control circuit 130 may output the first voltage VEXT to the mid voltage output circuit 110 based on the feedback based on the input voltage VIN having the level of the first voltage VEXT. For example, the pull-up voltage control circuit 130 may output a corresponding one of the first voltage VEXT and the positive target voltage VPOS to the mid voltage output circuit 110 according to the feedback voltage based on the voltage level of the input voltage VIN.

The pull-down voltage control circuit 140 may receive the second voltage VSS, the negative target voltage VNEG, and the feedback voltage, and may output the second voltage VSS or the negative target voltage VNEG based on the feedback voltage.

Referring to FIG. 2, the pull-down voltage control circuit 140 may output the second voltage VSS or the negative target voltage VNEG to the mid voltage output circuit 110 based on the feedback voltage.

For example, the pull-down voltage control circuit 140 may output the negative target voltage VNEG to the mid voltage output circuit 110 based on the feedback voltage VIN based on the input voltage VIN having the level of the first voltage VEXT. In some example embodiments, the pull-down voltage control circuit 140 may output the second voltage VSS to the mid voltage output circuit 110 based on the feedback voltage VIN based on the input voltage VIN having the level of the second voltage VSS. For example, the pull-down voltage control circuit 140 may output a corresponding one of the second voltage VSS and the negative target voltage VNEG to the mid voltage output circuit 110 according to the feedback voltage based on the voltage level of the input voltage VIN.

Accordingly, the pull-up voltage control circuit 130 and the pull-down voltage control circuit 140 may complementarily output a corresponding one of the positive target voltage VPOS and the negative target voltage VNEG to the mid voltage output circuit 110 according to the feedback voltage based on the voltage level of the input voltage VIN.

Referring to FIG. 3, the mid voltage output circuit 110 may include a pull-up circuit 111 and a pull-down circuit 113.

The pull-up circuit 111 may receive one of the first voltage VEXT or the positive target voltage VPOS, as well as the input voltage VIN, and may output the positive target voltage VPOS as the mid voltage VMID based on the input voltage VIN.

The pull-down circuit 113 may receive one of the second voltage VSS or the negative target voltage VNEG, as well as the input voltage VIN, and may output the negative target voltage VNEG as the mid voltage VMID based on the input voltage VIN.

Referring to FIG. 3, when the input voltage VIN level is the second voltage VSS level, the pull-up circuit 111 may output the positive target voltage VPOS as the mid voltage VMID. When the level of the input voltage VIN is the level of the second voltage VSS, the mid voltage VMID may correspond to the positive target voltage VPOS. In this case, the connection between the pull-down circuit 113 and the node to which the mid voltage is applied may be electrically opened by the input voltage VIN having the second voltage VSS level.

Referring to FIG. 3, when the input voltage VIN level is the first voltage EXT level, the pull-down circuit 113 may output the negative target voltage VNEG as the mid voltage VMID. Here, when the level of the input voltage VIN is the level of the first voltage EXT, the mid voltage VMID may correspond to the negative target voltage VNEG. In this case, the connection between the pull-up circuit 111 and the node to which the mid voltage VMID is applied may be electrically opened by the input voltage VIN having the first voltage EXT level.

For example, the mid voltage VMID may correspond to one of the positive target voltage VPOS and the negative target voltage VNEG according to the level of the input voltage VIN.

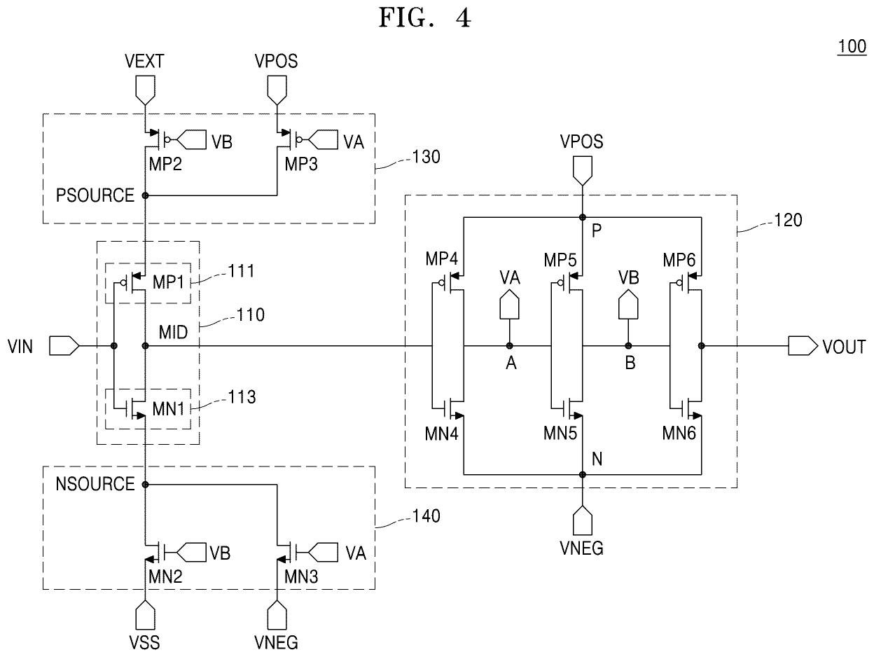

FIG. 4 is a diagram showing an equivalent circuit of a level shifter according to some example embodiments.

The level shifter 100 described with reference to FIGS. 2 and 3 may be implemented with a plurality of N-channel transistors and/or a plurality of P-channel transistors. For example, the N-channel transistor may be implemented as an N-type metal oxide semiconductor (NMOS) transistor, and the P-channel transistor may be implemented as a P-type metal oxide semiconductor (PMOS) transistor. Hereinafter, an MPx transistor refers to an x-th PMOS transistor, and an MNy transistor refers to a y-th NMOS transistor (where each of x and y is a positive integer greater than or equal to one). For example, referring to FIG. 4, the level shifter 100 according to some example embodiments may include an MP1 transistor, an MP2 transistor, an MP3 transistor, an MP4 transistor, an MP5 transistor, an MP6 transistor, an MN1 transistor, an MN2 transistor, an MN3 transistor, an MN4 transistor, an MN5 transistor, and an MN6 transistor.

However, in some example embodiments, cases in which N-channel transistors are implemented as NMOS transistors and P-channel transistors are implemented as PMOS transistors will be described as examples, but example embodiments are not limited thereto. For example, in some example embodiments, N-channel transistors and/or P-channel transistors may be implemented as transistors that perform switching and/or amplification operations one or more of (e.g., a Junction Field-Effect Transistor (JFET), a Metal-Semiconductor Field-Effect Transistor (MESFET), a High Electron Mobility Transistor (HEMT), an Insulated-Gate Bipolar Transistor (IGBT), etc.).

In some example embodiments, electrical and/or physical properties of each of the MPx and/or the MNy transistors may be the same as each other; alternatively, at least one electrical and/or physical property of at least one of the MPx and/or the MNy transistors may be different from at least one other of the MPx and/or MPy transistors. In some example embodiments, electrical properties may include one or more threshold voltage or on-state current, and physical properties may include one or more of gate length, gate width, and gate thickness. Example embodiments are not limited thereto.

Referring to FIGS. 2 to 4, the level shifter 100 may include the mid voltage output circuit 110, the feedback circuit 120, the pull-up voltage control circuit 130, and the pull-down voltage control circuit 140. Here, the mid voltage output circuit 110 may include the pull-up circuit 111 and the pull-down circuit 113.

Referring to FIG. 4, the mid voltage output circuit 110 may include an MP1 transistor and an MN1 transistor. In addition, the pull-up circuit 111 may include (or correspond to) an MP1 transistor, and the pull-down circuit 113 may include (or correspond to) an MN1 transistor.

The gate terminal of the MP1 transistor may be connected to the input voltage VIN line. The source terminal of the MP1 transistor may be connected to a node PSOURCE. The drain terminal of the MP1 transistor may be connected to a node MID.

When the input voltage VIN level is the first voltage VEXT, the MP1 transistor is turned off so that the MP1 transistor may electrically open the node PSOURCE and the node MID. When the input voltage VIN level is the second voltage VSS, the MP1 transistor is turned on so that the MP1 transistor may allow a current from the node PSOURCE to flow to the node MID.

In some example embodiments, based on the level of the input voltage VIN, the MP1 transistor may allow the current from the node PSOURCE to flow to the node MID, or the MP1 transistor may electrically open the node PSOURCE and the node MID.

The gate terminal of the MN1 transistor may be connected to the input voltage VIN line. The source terminal of the MN1 transistor may be connected to a node NSOURCE. The drain terminal of the MN1 transistor may be connected to the node MID.

When the input voltage VIN level is the second voltage VSS, the MN1 transistor is turned off, and thus the MN1 transistor may electrically open the node NSOURCE and the node MID. When the input voltage VIN level is the first voltage VEXT, the MN1 transistor is turned on, and thus the MN1 transistor may allow a current from the node NSOURCE to flow to the node MID.

For example, based on the level of the input voltage VIN, the MN1 transistor may allow a current from the node NSOURCE to flow to the node MID, or the MN1 transistor may electrically open the node NSOURCE and the node MID.

Referring to FIG. 4, the pull-up voltage control circuit 130 may include an MP2 transistor and an MP3 transistor. In addition, the pull-down voltage control circuit 140 may include an MN2 transistor and an MN3 transistor.

The gate terminal of the MP2 transistor may be connected to a node B. The source terminal of the MP2 transistor may be connected to the first voltage VEXT line. The drain terminal of the MP2 transistor may be connected to the node PSOURCE.

The gate terminal of the MP3 transistor may be connected to a node A. The source terminal of the MP3 transistor may be connected to the positive target voltage VPOS line. The drain terminal of the MP3 transistor may be connected to the node PSOURCE.

The gate terminal of the MN2 transistor may be connected to the node B. The source terminal of the MN2 transistor may be connected to the second voltage VSS line. The drain terminal of the MN2 transistor may be connected to the node NSOURCE.

The gate terminal of the MN3 transistor may be connected to the node A. The source terminal of the MN3 transistor may be connected to the negative target voltage VNEG line. The drain terminal of the MN3 transistor may be connected to the node NSOURCE.

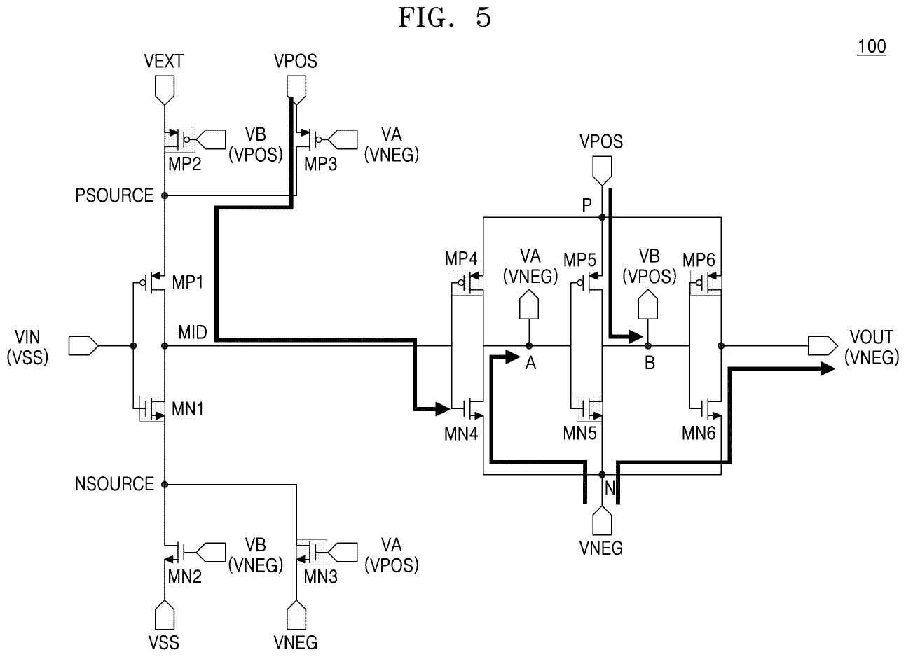

Operations of each of the MP2 transistor, the MP3 transistor, the MN2 transistor, and the MN3 transistor are described in detail with reference to FIGS. 5 to 7.

Referring to FIG. 4, the feedback circuit 120 may include an MP4 transistor, an MP5 transistor, an MP6 transistor, an MN4 transistor, an MN5 transistor, and an MN6 transistor.

The gate terminal of the MP4 transistor may be connected to the node MID. The source terminal of the MP4 transistor may be connected to a node P. The drain terminal of the MP4 transistor may be connected to a node A.

The source terminal of the MN4 transistor may be connected to a node N. The drain terminal of the MN4 transistor may be connected to the node A.

The gate terminal of the MP5 transistor may be connected to the node A. The source terminal of the MP5 transistor may be connected to the node P. The drain terminal of the MP5 transistor may be connected to the node B.

The gate terminal of the MN5 transistor may be connected to the node A. The source terminal of the MN5 transistor may be connected to the node N. The drain terminal of the MN5 transistor may be connected to the node B.

The gate terminal of the MP6 transistor may be connected to the node B. The source terminal of the MP6 transistor may be connected to the node P. The drain terminal of the MP6 transistor may be connected to the output voltage VOUT line.

The gate terminal of the MN6 transistor may be connected to the node B. The source terminal of the MN6 transistor may be connected to the node N. The drain terminal of the MN6 transistor may be connected to the output voltage VOUT line.

Operations of each of the MP4 transistor, MP5 transistor, MP6 transistor, MN4 transistor, MN5 transistor, and MN6 transistor are described in detail with reference to FIGS. 5 to 7.

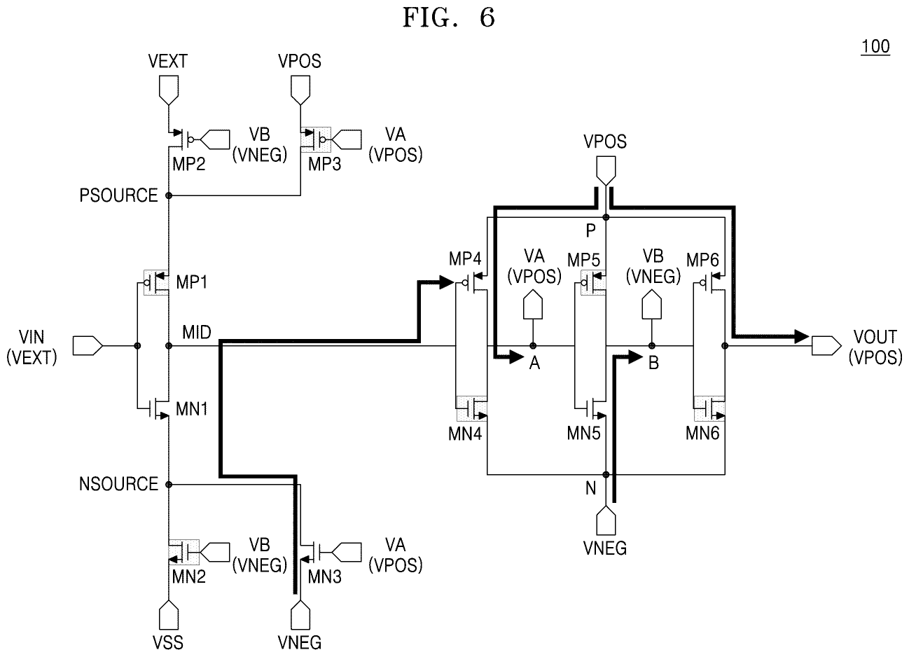

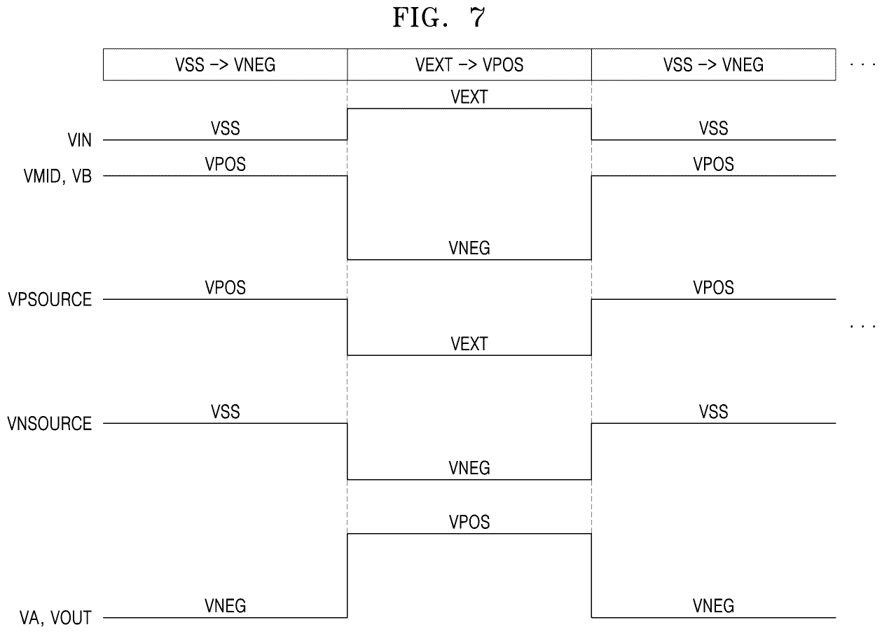

Hereinafter, the operation of the level shifter 100 described with reference to FIG. 4 is described by dividing the level of the input voltage VIN into a section (VSS->VNEG) which is the second voltage VSS and a section (VEXT->VPOS) which is the first voltage VEXT. Specifically, the section (VSS->VNEG) is described with reference to FIGS. 5 and 7, and the section (VEXT->VPOS) is described with reference to FIGS. 6 and 7.

FIG. 5 is a diagram to explain the operation of a level shifter in a section (VSS->VNEG) according to some example embodiments. FIG. 6 is a diagram to explain the operation of a level shifter in a section (VEXT->VPOS) according to some example embodiments. FIG. 7 is a timing diagram to explain the operation of a level shifter in each of the sections (VSS->VNEG) and (VEXT->VPOS) according to some example embodiments.

The operation according to the timing diagram of FIG. 7 may be performed by the level shifter 100 of FIG. 4. Referring to FIG. 7, the operation of the level shifter 100 of FIG. 4 is illustrated as being performed in the order of section (VEXT->VPOS), section (VSS->VNEG) and section (VEXT->VPOS), but is not limited thereto, and the operation of the level shifter 100 of FIG. 4 may be performed in a section in which at least one section (VEXT->VPOS) and at least one section (VSS->VNEG) are sequentially and/or repeatedly included.

A section (VSS->VNEG) in which the level of the input voltage VIN is the level of the second voltage VSS is described with reference to FIGS. 5 and 7.

Referring to FIG. 5, when the input voltage VIN level is the second voltage VSS, the MP1 transistor is turned on, and thus, the MP1 transistor may allow a current from the node PSOURCE to flow to the node MID. Accordingly, the positive target voltage VPOS is applied to the gate terminal of the MN4 transistor through the MP3 transistor, the node PSOURCE, the MP1 transistor, and the node MID, and thus, the MN4 transistor may be turned on. At the same time, as the MN4 transistor is turned on, the negative target voltage VNEG is applied to the gate terminal of each of the MP3 and MP5 transistors through the node N, the MN4 transistor, and the node A, and thus, the MP3 transistor and MP5 transistor may be turned on. In addition, at the same time, as the MP5 transistor is turned on, the positive target voltage VPOS is applied to the gate terminal of each of the MN6 transistor and the MN2 transistor through the MP5 transistor and the node B, and thus, the MN6 transistor and the MN2 transistor may be turned on. As the MN6 transistor is turned on, the negative target voltage VNEG may be applied to the output voltage VOUT line through the node N and the MN6 transistor.

Here, when the input voltage VIN level is the second voltage VSS, the MN1 transistor is turned off, and thus the MN1 transistor may electrically open the node NSOURCE and the node MID. In addition, the positive target voltage VPOS is applied to the gate terminal of the MP4 transistor through the MP3 transistor, the node PSOURCE, the MP1 transistor, and the node MID, and thus, the MP4 transistor may be turned off. In addition, the negative target voltage VNEG is applied to the gate terminal of each of the MN3 transistor and the MN5 transistor through the node N, the MN4 transistor, and node A, and thus, the MN3 transistor and the MN5 transistor may be turned off. The positive target voltage VPOS is applied to the gate terminal of each of the MP6 transistor and the MP2 transistor through the MP5 transistor and the node B, and thus, the MP6 transistor and the MP2 transistor may be turned off.

Referring to FIGS. 5 and 7, it may be seen that the level of the input voltage VIN is the level of the second voltage VSS in the section (VSS->VNEG). The MP1 transistor may be turned on and the MN1 transistor may be turned off based on the input voltage VIN level having the second voltage VSS level. Accordingly, a current path from the pull-up voltage control circuit 130 may be selected.

Meanwhile, the feedback voltage may include a voltage VA applied to the node A and a voltage VB applied to the node B. Referring to FIG. 7, as described above, when the input voltage VIN level is the second voltage VSS level, the corresponding voltage VA level may correspond to a negative target voltage VNEG level, and the corresponding voltage VB level may correspond to a positive target voltage VPOS level. Accordingly, the MP3 transistor included in the pull-up voltage control circuit 130 and the MN2 transistor included in the pull-down voltage control circuit 140 may be turned on.

The mid voltage VMID may correspond to the voltage level of the node MID. As the MP3 transistor is turned on by the feedback voltage described above, the positive target voltage VPOS may be applied to the node MID from the positive target voltage VPOS line. Here, the MP1 transistor may be turned on and the MN1 transistor may be turned off by the level of the second voltage VSS.

Accordingly, referring to FIG. 7, it may be seen that the mid voltage VMID is the positive target voltage VPOS level. In addition, in this case, since the node MID and the node PSOURCE are electrically connected to each other, the voltage VPSOURCE level of the node PSOURCE may also be the positive target voltage VPOS level. Meanwhile, in this case, since the node MID and the node NSOURCE are electrically opened and the MN2 transistor is turned on by the feedback voltage, the voltage VNSOURCE level of the node NSOURCE may be the second voltage VSS level by the second voltage VSS applied from the second voltage VSS line. In addition, as described above, as the negative target voltage VNEG is applied to the output voltage VOUT line through the node N and the MN6 transistor, the output voltage VOUT level may be the negative target voltage VNEG level.

Hereinafter, with reference to FIGS. 6 and 7, the section (VEXT->VPOS) where the input voltage VIN level is the first voltage VEXT level is described.

Referring to FIG. 6, when the input voltage VIN level is the first voltage VEXT, the MN1 transistor is turned on, and thus, the MN1 transistor may allow a current from the node NSOURCE to flow to the node MID. Accordingly, the negative target voltage VNEG is applied to the gate terminal of the MP4 transistor through the MN3 transistor, the node NSOURCE, the MN1 transistor, and the node MID, and thus, the MP4 transistor may be turned on. At the same time, as the MP4 transistor is turned on, the positive target voltage VPOS is applied to the gate terminal of each of the MN3 transistor and the MN5 transistor through the node P, the MP4 transistor, and the node A, and thus, the MN3 transistor and the MN5 transistor may be turned on. In addition, at the same time, as the MN5 transistor is turned on, the negative target voltage VNEG is applied to the gate terminal of each of the MP6 transistor and the MP2 transistor through the MN5 transistor and the node B, and thus, the MP6 transistor and the MP2 transistor may be turned on. As the MP6 transistor is turned on, the positive target voltage VPOS may be applied to the output voltage VOUT line through the node P and the MP6 transistor.

Here, when the input voltage VIN level is the first voltage VEXT, the MP1 transistor is turned off, and thus, the MP1 transistor may electrically open the node PSOURCE and the node MID. In addition, the negative target voltage VNEG is applied to the gate terminal of the MN4 transistor through the MN3 transistor, the node NSOURCE, the MN1 transistor, and the node MID, and thus, the MN4 transistor may be turned off. In addition, the positive target voltage VPOS is applied to the gate terminal of each of the MP3 transistor and the MP5 transistor through the node P, the MP4 transistor, and the node A, and thus, the MP3 transistor and the MP5 transistor may be turned off. The negative target voltage VNEG is applied to the gate terminal of each of the MN6 transistor and the MN2 transistor through the MN5 transistor and the node B, and thus, the MN6 transistor and the MN2 transistor may be turned off.

Referring to FIGS. 6 and 7, it may be seen that the level of the input voltage VIN is the level of the first voltage VEXT in the section (VEXT->VPOS). The MN1 transistor may be turned on and the MP1 transistor may be turned off based on the input voltage VIN level having the first voltage VEXT level. Accordingly, a current path from the pull-down voltage control circuit 140 may be selected.

Meanwhile, the feedback voltage may include the voltage VA applied to the node A and the voltage VB applied to the node B. Referring to FIG. 7, as described above, when the input voltage VIN level is the first voltage VEXT level, the corresponding voltage VA level may correspond to a positive target voltage VPOS level, and the corresponding voltage VB level may correspond to a negative target voltage VNEG level. Accordingly, the MP2 transistor included in the pull-up voltage control circuit 130 and the MN3 transistor included in the pull-down voltage control circuit 140 may be turned on.

The mid voltage VMID may correspond to the voltage level of the node MID. As the MN3 transistor is turned on by the feedback voltage described above, the negative target voltage VNEG may be applied to the node MID from the negative target voltage VNEG line. Here, the MN1 transistor may be turned on and the MP1 transistor may be turned off by the level of the first voltage VEXT.

Accordingly, referring to FIG. 7, it may be seen that the mid voltage VMID level is the negative target voltage VNEG level. In addition, in this case, since the node MID and the node NSOURCE are electrically connected to each other, the voltage VNSOURCE level of the node NSOURCE may also be the negative target voltage VNEG level. Meanwhile, in this case, since the node MID and the node PSOURCE are electrically opened and the MP2 transistor is turned on by the feedback voltage, the voltage VPSOURCE level of the node PSOURCE may be the first voltage VEXT level by the first voltage VEXT applied from the first voltage VEXT line. In addition, as described above, as the positive target voltage VPOS is applied to the output voltage VOUT line through the node P and the MP6 transistor, the output voltage VOUT level may be the positive target voltage VPOS level.

In the level shifter 100 according to some example embodiments, as the level shifter 100 performs the operation described with reference to FIGS. 2 to 7, the single level shifter 100 outputs a positive voltage as a positive target voltage and a negative voltage as a negative target voltage so that both the positive voltage and the negative voltage may be output as a corresponding positive target voltage and a corresponding negative target voltage through the single level shifter 100. Accordingly, when a semiconductor circuit is designed, a silicon area cost for the level shifter 100 may be reduced.

In the level shifter 100 according to some example embodiments, a connection between the pull-down circuit 113 and the node MID outputting the mid voltage is electrically opened by the input voltage VIN having the second voltage VSS level or a connection between the pull-up circuit 111 and the node MID outputting the mid voltage is electrically opened by the input voltage VIN having the first voltage EXT level so that the level shifter 100 may output a positive voltage as a positive target voltage and a negative voltage as a negative target voltage with no leakage current path.

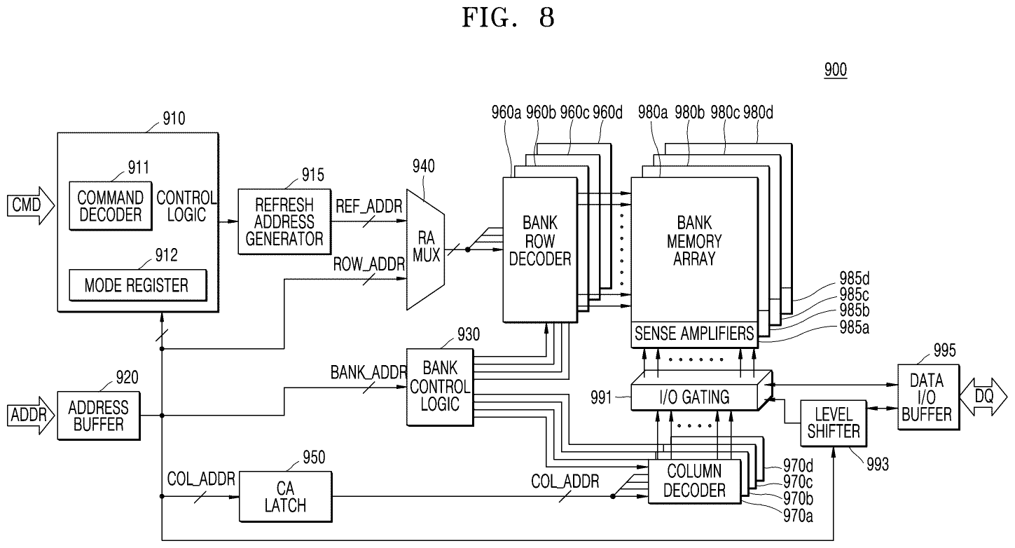

FIG. 8 is a diagram illustrating a memory device including a level shifter according to some example embodiments.

Referring to FIG. 8, a memory device 900 may include a control logic 910, a refresh address generator 915, an address buffer 920, a bank control logic 930, a row address multiplexer 940, a column address latch 950, a row decoder, a column decoder, a memory cell array, a sense amplifier unit, an input/output gating circuit 991, a level shifter 993, and a data input/output buffer 995. Here, the level shifter 993 may correspond to the level shifters 1 and 100 described with reference to FIGS. 1 to 7. In some example embodiments, the input/output gating circuit 991, the level shifter 993, and the data input/output buffer 995 may be implemented as a single input/output circuit.

The memory cell array may include first to fourth bank memory arrays 980a, 980b, 980c, and 980d. The row decoder may include first to fourth bank row decoders 960a, 960b, 960c, and 960d connected to the first to fourth bank memory arrays 980a, 980b, 980c, and 980d, respectively. The column decoder may include first to fourth bank column decoders 970a, 970b, 970c, and 970d connected to the first to fourth bank memory arrays 980a, 980b, 980c, and 980d, respectively. The sense amplifier unit may include first to fourth bank sense amplifiers 985a, 985b, 985c, and 985d connected to the first to fourth bank memory arrays 980a, 980b, 985c, and 980d, respectively. The first to fourth bank memory arrays 980a, 980b, 980c, and 980d, the first to fourth bank row decoders 960a, 960b, 960c, and 960d, the first to fourth bank column decoders 970a, 970b, 970c, and 970d, and the first to fourth bank sense amplifiers 985a, 985b, 985c, and 985d may constitute first to fourth banks, respectively. Although an example of the memory device 900 including four banks is illustrated in FIG. 8, depending on example embodiments, the memory device 900 may include any number of banks, such as more than four or less than four banks.

Alternatively or additionally, according to some example embodiments, the memory device 900 may be or include or may be included in one or more of dynamic random access memory (DRAM) such as Double Data Rate Synchronous Dynamic Random Access Memory (DDR SDRAM), Low Power Double Data Rate (LPDDR) SDRAM, Graphics Double Data Rate (GDDR) SDRAM, Rambus Dynamic Random Access Memory (RDRAM), or any volatile memory device that requires a refresh operation.

The control logic 910 may control operations of the memory device 900. For example, the control logic 910 may generate control signals for the memory device 900 to perform a write operation or a read operation. The control logic 910 may include a command decoder 911 for decoding a command CMD received from a memory controller and a mode register 912 for setting an operation mode of the memory device 900. For example, the command decoder 911 may decode a write enable signal/WE, a row address strobe signal/RAS, a column address strobe signal/CAS, and a chip selection signal/CS to generate control signals corresponding to the command CMD.

The control logic 910 may further receive a clock CLK and a clock enable signal CKE for driving the memory device 900 in a synchronous manner. The control logic 910 may control the refresh address generator 915 to perform an auto-refresh operation in response to a refresh command, or control the refresh address generator 915 to perform a self-refresh operation in response to a self-refresh entry command.

The refresh address generator 915 may generate a refresh address REF_ADDR corresponding to a memory cell row in which a refresh operation is to be performed. The refresh address generator 915 may generate the refresh address REF_ADDR at a refresh rate of a cycle longer than a refresh cycle defined in the standard of the memory device 900. Accordingly, the refresh current and/or refresh power of the memory device 900 may be reduced.

The address buffer 920 may receive an address ADDR including a bank address BANK_ADDR, a row address ROW_ADDR, and a column address COL_ADDR from the memory controller. In addition, the address buffer 920 may provide the received bank address BANK_ADDR to the bank control logic 930, the received row address ROW_ADDR to the row address multiplexer 940, and the received column address COL_ADDR to the column address latch 950.

The bank control logic 930 may generate bank control signals in response to the bank address BANK_ADDR. In response to the bank control signals, a bank row decoder corresponding to the bank address BANK_ADDR among the first to fourth bank row decoders 960a, 960b, 960c, and 960d may be activated, and a bank column decoder corresponding to the bank address BANK_ADDR among the first to fourth bank column decoders 970a, 970b, 970c, and 970d may be activated.

The bank control logic 930 may generate bank group control signals in response to the bank address BANK_ADDR determining a bank group. In response to the bank group control signals, row decoders of the bank group corresponding to the bank address BANK_ADDR among the first to fourth bank row decoders 960a, 960b, 960c, and 960d may be activated, and column decoders of the bank group corresponding to the bank address BANK_ADDR among the first to fourth bank column decoders 970a, 970b, 970c, and 970d may be activated.

The row address multiplexer 940 may receive the row address ROW_ADDR from the address buffer 920 and the refresh row address REF_ADDR from the refresh address generator 915. The row address multiplexer 940 may selectively output the row address ROW_ADDR or the refresh row address REF_ADDR. The row address output from the row address multiplexer 940 may be applied to each of the first to fourth bank row decoders 960a, 960b, 960c, and 960d.

The bank row decoder activated by the bank control logic 930 among the first to fourth bank row decoders 960a, 960b, 960c, and 960d may decode the row address output from the row address multiplexer 940 to activate a word line corresponding to the row address. For example, the activated bank row decoder may apply a word line driving voltage to the word line corresponding to the row address.

The column address latch 950 may receive the column address COL_ADDR from the address buffer 920 and temporarily store the received column address COL_ADDR. The column address latch 950 may gradually increase the received column address COL_ADDR in a burst mode. The column address latch 950 may apply the temporarily stored or gradually increased column address COL_ADDR to each of the first to fourth bank column decoders 970a, 970b, 970c, and 970d.

Among the first to fourth bank column decoders 970a, 970b, 970c, and 970d, the bank column decoder activated by the bank control logic 930 may activate a sense amplifier corresponding to the bank address BANK_ADDR and the column address COL_ADDR through the input/output gating circuit 991.

The input/output gating circuit 991, together with circuits for gating input/output data, may include an input data mask logic, read data latches for storing data output from the first to fourth bank memory arrays 980a, 980b, 980c, and 980d, and a write driver for writing data to the first to fourth bank memory arrays 980a, 980b, 980c, and 980d.

Data to be read from one of the first to fourth bank memory arrays 980a, 980b, 980c, and 980d may be sensed and amplified by a sense amplifier and stored in read data latches. The data DQ stored in the read data latches may be provided to the memory controller through the data input/output buffer 995. The data DQ to be written to one of the first to fourth bank memory arrays 980a, 980b, 980c, and 980d may be provided from the memory controller to the data input/output buffer 995. The data DQ provided to the data input/output buffer 995 may be written to one bank memory array through the write driver.

In some example embodiments, data read from one of the first to fourth bank memory arrays 980a, 980b, 980c, and 980d may be stored in the read data latches through the level shifter 993. The data DQ stored in the read data latches may be provided to the memory controller through the data input/output buffer 995.

In some example embodiments, the data DQ to be written to one of the first to fourth bank memory arrays 980a, 980b, 980c, and 980d may be provided from the memory controller to the data input/output buffer 995. The data DQ provided to the data input/output buffer 995 may be written to one bank memory array through the level shifter 993 and the write driver.

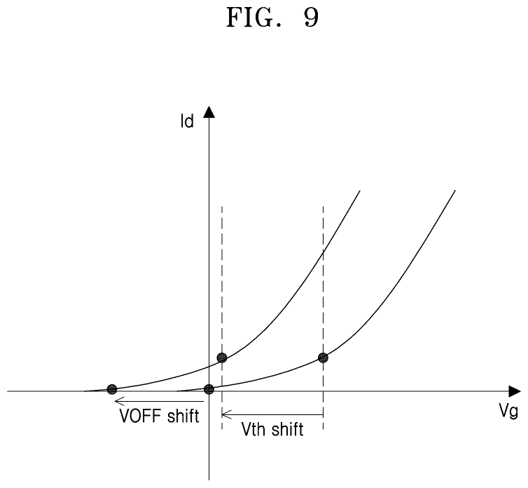

FIG. 9 is a graph to explain a level shifter according to some example embodiments. Specifically, FIG. 9 is a graph showing a change in a threshold voltage Vth level and a change in a turn-off voltage VOFF level according to miniaturization of a transistor. Here, a turn-off voltage VOFF may be a ground voltage level (e.g., 0 V) or a voltage close to the ground voltage.

As the integrated circuit implementing the memory device is miniaturized, the gate voltage should be lowered due to the reliability problem of the transistor. For example, here, the reliability problem of the transistor may include time-dependent dielectric breakdown (TDDB).

As a result, a turn-on current Ion, which is the operating current of the transistor, is reduced. To compensate for this, the threshold voltage Vth level of the transistor included in the integrated circuit should be reduced. Accordingly, unless the level of the turn-off voltage VOFF is lowered, the turn-off current Ioff of the transistor increases.

For example, unless the level of the turn-off voltage VOFF is lowered, power consumption of the memory device may increase due to the turn-off current Ioff of the transistor.

In the level shifter 100 according to some example embodiments, as the level shifter 100 performs the operation described with reference to FIGS. 2 to 7, the single level shifter 100 outputs a positive voltage as a positive target voltage and a negative voltage as a negative target voltage so that both the positive voltage and the negative voltage may be output as a corresponding positive target voltage and a corresponding negative target voltage through the single level shifter 100.

Accordingly, the turn-off voltage may be VOFF-shifted to correspond to the change in the threshold voltage (Vth shift) through the level shifter 100 according to some example embodiments.

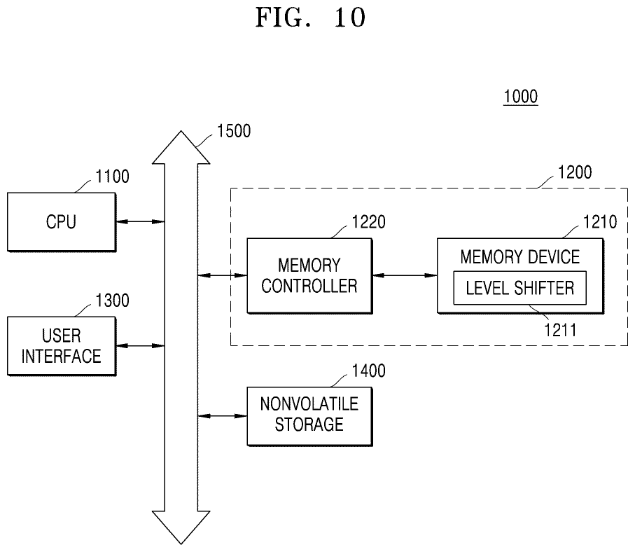

FIG. 10 is a block diagram of a computing system according to some example embodiments.

Referring to FIG. 10, a computing system 1000 may include a central processing unit (CPU) 1100, a memory system 1200, a user interface 1300, and a nonvolatile storage device 1400. The CPU 1100, the memory system 1200, the user interface 1300, and the nonvolatile storage device 1400 may communicate with each other through a bus 1500. Although not shown in FIG. 10, the computing system 1000 may further include ports capable of communicating with a video card, a sound card, a memory card, a universal serial bus (USB) device, or the like, or communicating with other electronic devices. The computing system 1000 may be implemented as a personal computer or a server, and may be implemented as a portable electronic device such as a notebook computer, a mobile phone, a personal digital assistant (PDA), a camera, and the like. When the computing system 1000 according to some example embodiments is a mobile device, a battery for supplying an operating voltage of the computing system 1000 and a modem such as a baseband chipset may be additionally provided. In addition, the computing system 1000 according to some example embodiments may further include an application chipset, a camera image processor (CIS), and mobile DRAM.

The CPU 1100 may perform specific calculations or tasks. According to embodiments, the CPU 1110 may be a microprocessor or a graphics processing unit (GPU). The CPU 1100 may communicate with the memory system 1200, the user interface 1300, and the nonvolatile storage device 1400 through the bus 1500. The CPU 1100 may also be connected to an expansion bus such as but not limited to a peripheral component interconnect (PCI) bus.

The memory system 1200 may include a memory device 1210 and a memory controller 1220, and may store data necessary for the operation of the computing system 1000. For example, the memory system 1200 may function as a data memory of the CPU 1100, and may store data received from the bus 1500 or transmit stored data to the bus 1500 by supporting direct memory access (DMA).

The memory device 1210 may include a level shifter 1211. Here, the level shifter 1211 of FIG. 10 may correspond to one of the embodiments described above. That is, the level shifter 1211 may be the level shifter according to the embodiments.

The level shifter 1211 may change the voltage level of the voltage applied from the power supply device (or an external device) and apply the voltage to the memory device 1210. However, the level shifter 1211 may output the voltage of which the voltage level has been changed to a device other than the memory device 1210. Although FIG. 10 separately shows the level shifter 1211 and the memory controller 1220, the memory controller 1220 may include the level shifter 1211 and the level shifter 1211 may be provided as a separate device.

The user interface 1300 may include an input unit such as a keyboard, a keypad, or a mouse to receive an input signal from a user, and may include an output unit such as a printer or a display device to provide an output signal to the user.

The nonvolatile storage device 1400 may include, for example, one or more of an electrically erasable programmable read-only memory (EEPROM), flash memory, phase change random access memory (PRAM), Resistance Random Access Memory (RRAM), Nano Floating Gate Memory (NFGM), Polymer Random Access Memory (PoRAM), Magnetic Random Access Memory (MRAM), Ferroelectric Random Access Memory (FRAM), etc., and in some example embodiments may include a magnetic disk, etc.

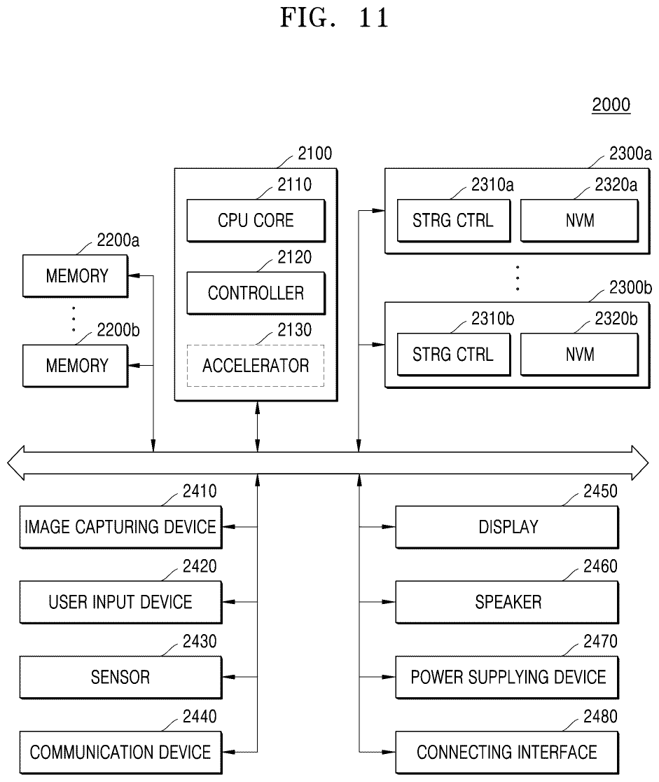

FIG. 11 is a block diagram illustrating a system to which a storage device according to some example embodiments is applied.

Referring to FIG. 11, a system 2000 of FIG. 11 may include a mobile system, such as a mobile phone, a smartphone, a tablet personal computer (PC), a wearable device, a healthcare device, or an Internet of Things (IoT) device. However, the system 2000 of FIG. 11 is not necessarily limited to a mobile system and may include a PC, a laptop computer, a server, a media player, or an automotive device such as a navigation.

Referring to FIG. 11, the system 2000 may include a main processor 2100, memories 2200a and 2200b, and storage devices 2300a and 2300b. In addition, the system 2000 may include one or more of an image capturing device 2410, a user input device 2420, a sensor 2430, a communication device 2440, a display 2450, a speaker 2460, a power supplying device 2470, and a connecting interface 2480.

The main processor 2100 may control the overall operation of the system 2000, more specifically, the operation of other components constituting the system 2000. The main processor 2100 may be implemented as a general-purpose processor, a dedicated processor, an application processor, or the like.

The main processor 2100 may include one or more CPU cores 2110 and may further include a controller 2120 for controlling the memories 2200a and 2200b and/or the storage devices 2300a and 2300b. According to some example embodiments, the main processor 2100 may further include an accelerator 2130, which is a dedicated circuit for high-speed data operations such as an artificial intelligence (AI) data operation. The accelerator 2130 may include a PU, a neural processing unit (NPU), and/or a data processing unit (DPU) and may be implemented as a separate chip physically independent of other components of the main processor 2100.

The memories 2200a and 2200b may be used as main memory devices of the system 2000 and may include volatile memories, such as SRAM and/or DRAM, but may also include nonvolatile memories, such as flash memory, PRAM and/or RRAM. The memories 2200a and 2200b may be implemented in the same package as the main processor 2100.

According to some example embodiments, the memories 2200a and 2200b may correspond to the memory device 1210 of FIG. 10, and the memories 2200a and 2200b may include the level shifters 1 and 100 according to some example embodiments.

The storage devices 2300a and 2300b may function as nonvolatile storage devices that store data regardless of whether power is supplied to the storage devices, and may have a relatively large storage capacity compared to the memories 2200a and 2200b. The storage devices 2300a and 2300b may respectively include storage controllers 2310a and 2310b and nonvolatile memories 2320a and 2320b that store data under control by the storage controllers 2310a and 2310b. The nonvolatile memories 2320a and 2320b may include flash memory having a 2-dimensional (2D) structure and/or a 3-dimensional (3D) Vertical NAND (V-NAND) structure but may include other types of nonvolatile memories such as PRAM and/or RRAM.

The storage devices 2300a and 2300b may be included in the system 2000 by being physically separated from the main processor 2100, or may be implemented in the same package as the main processor 2100. In addition, the storage devices 2300a and 2300b may be detachably combined with other components of the system 2000 through an interface such as the connecting interface 2480, which is described below, by having a form such as a solid state device (SSD) or a memory card. The storage devices 2300a and 2300b may be devices to which standard protocols such as one or more of Universal Flash Storage (UFS), embedded multi-media card (eMMC), or nonvolatile memory express (NVMe) are applied, but are not necessarily limited thereto.

The image capturing device 2410 may capture a still image and/or a moving image and may include one or more of a camera, a camcorder, and/or a webcam.

The user input device 2420 may receive various types of data input from a user of the system 2000 and may include a touch pad, a keypad, a keyboard, a mouse, and/or a microphone.

The sensor 2430 may detect various types of physical quantities that may be obtained from the outside of the system 2000 and convert the detected physical quantities into electrical signals. The sensor 2430 may include one or more of a temperature sensor, a pressure sensor, an illuminance sensor, a position sensor, an acceleration sensor, a biosensor, and/or a gyroscope sensor.

The communication device 2440 may transmit and/or receive signals to and from other devices outside the system 2000 according to various communication protocols. The communication device 2440 may be implemented by including one or more of an antenna, a transceiver, and/or a modem.

The display 2450 and the speaker 2460 may function as output devices that output visual information and auditory information to users of the system 2000, respectively.

The power supplying device 2470 may appropriately convert power supplied from a battery (not shown) embedded in the system 2000 and/or an external power source into the system 2000 and supply the power to each component of the system 2000.

The connecting interface 2480 may provide a connection between the system 2000 and an external device connected to the system 2000 and be capable of transmitting and receiving data to and from the system 2000. The connecting interface 2480 may be implemented in a variety of interface methods such as one or more of Advanced Technology Attachment (ATA), Serial ATA (SATA), External SATA (e-SATA), Small Computer Small Interface (SCSI), Serial Attached SCSI (SAS), PCI, PCI express (PCIe), NVMe, IEEE 1394, universal serial bus (USB), Secure Digital (SD) card interface, MMC, eUFS, Compact Flash (CF) card interface, and/or the like.

Any or all of the elements described with reference to the figures may communicate with any or all other elements described with reference to the corresponding figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various example embodiments have been particularly shown and described with reference to embodiments thereof, it will be understood that various changes in form and details may be made therein without departing from the spirit and scope of the following claims. Example embodiments are not necessarily mutually exclusive. For example, some example embodiments may include one or more features described with reference to one or more figures, and may also include one or more other features described with reference to one or more other figures.

What is claimed is:

1. A level shifter comprising:
a mid voltage output circuit configured to output a mid voltage based on an input voltage swinging between a first voltage level and a second voltage level;
a feedback circuit configured to output a feedback voltage and an output voltage that swings between a positive target voltage level and a negative target voltage level, the output of the feedback circuit based on the positive target voltage, the negative target voltage and the mid voltage;
a pull-up voltage control circuit configured to output at least one of a first voltage or the positive target voltage to the mid voltage output circuit, the output of the pull-up voltage control circuit based on the feedback voltage; and
a pull-down voltage control circuit configured to output at least one of a second voltage or the negative target voltage to the mid voltage output circuit, the output of the pull-down voltage control circuit based on the feedback voltage.

2. The level shifter of claim 1, wherein the mid voltage output circuit comprises:
a pull-up circuit configured to output the positive target voltage as the mid voltage based on the input voltage; and
a pull-down circuit configured to output the negative target voltage as the mid voltage based on the input voltage.

3. The level shifter of claim 2, wherein,
in response to the level of the input voltage being the first voltage level, a connection between the pull-up circuit and a node to which the mid voltage is applied is electrically opened, and
in response to the level of the input voltage being the second voltage level, a connection between the pull-down circuit and the node to which the mid voltage is applied is electrically opened.

4. The level shifter of claim 1, wherein the feedback circuit determines the feedback voltage based on a voltage level of the input voltage.

5. The level shifter of claim 2, wherein the pull-up voltage control circuit and the pull-down voltage control circuit are configured to complementarily output a corresponding one of the positive target voltage and the negative target voltage to the mid voltage output circuit according to the feedback voltage based on a voltage level of the input voltage.

6. The level shifter of claim 2, wherein
the pull-up voltage control circuit is configured to output the positive target voltage to the mid voltage output circuit, based on the feedback voltage and on the input voltage having the second voltage level, and
the pull-down voltage control circuit is configured to output the negative target voltage to the mid voltage output circuit, based on the feedback voltage and on the input voltage having the first voltage level.

7. The level shifter of claim 2, wherein
the pull-up voltage control circuit is configured to output the positive target voltage to the mid voltage output circuit, based on the feedback voltage and on the input voltage having the second voltage level,
the mid voltage output circuit is configured to output the positive target voltage as the mid voltage based on the input voltage having the second voltage level, and
the feedback circuit is configured to output an output voltage having a negative target voltage level based on the positive target voltage.

8. The level shifter of claim 2, wherein
the pull-down voltage control circuit is configured to output the negative target voltage to the mid voltage output circuit, based on the feedback voltage and on the input voltage having the first voltage level,
the mid voltage output circuit is configured to output the negative target voltage as the mid voltage based on the input voltage having the first voltage level, and
the feedback circuit is configured to output an output voltage having a positive target voltage level based on the negative target voltage.

9. A level shifter comprising:
a first P-channel transistor having a gate terminal connected to an input voltage line, a source terminal connected to a first node, and a drain terminal connected to a second node;
a first N-channel transistor having a gate terminal connected to the input voltage line, a source terminal connected to a third node, and a drain terminal connected to the second node;
a second P-channel transistor having a gate terminal connected to a fourth node, a source terminal connected to a first voltage line, and a drain terminal connected to the first node;
a third P-channel transistor having a gate terminal connected to a fifth node, a source terminal connected to a positive target voltage line, and a drain terminal connected to the first node;
a second N-channel transistor having a gate terminal connected to the fourth node, a source terminal connected to a second voltage line, and a drain terminal connected to the third node;
a third N-channel transistor having a gate terminal connected to the fifth node, a source terminal connected to a negative target voltage line, and a drain terminal connected to the third node;
a fourth P-channel transistor having a gate terminal connected to the second node, a source terminal connected to a sixth node, and a drain terminal connected to the fifth node;
a fourth N-channel transistor having a gate terminal connected to the second node, a source terminal connected to a seventh node, and a drain terminal connected to the fifth node;
a fifth P-channel transistor having a gate terminal connected to the fifth node, a source terminal connected to the sixth node, and a drain terminal connected to the fourth node;
a fifth N-channel transistor having a gate terminal connected to the fifth node, a source terminal connected to the seventh node, and a drain terminal connected to the fourth node;
a sixth P-channel transistor having a gate terminal connected to the fourth node, a source terminal connected to the sixth node, and a drain terminal connected to an output voltage line; and
a sixth N-channel transistor having a gate terminal connected to the fourth node, a source terminal connected to the seventh node, and a drain terminal connected to the output voltage line, wherein
the sixth node is connected to the positive target voltage line, and the seventh node is connected to the negative target voltage line.

10. The level shifter of claim 9, wherein
the input voltage line is configured to have an input voltage applied that swings between a first voltage level and a second voltage level, and
the output voltage line is configured to have the output voltage applied that swings between a positive target voltage level and a negative target voltage level.

11. The level shifter of claim 10, wherein
the first P-channel transistor is configured to turn on based on the input voltage having the second voltage level,
the fourth N-channel transistor is configured to turn on based on a positive target voltage from the positive target voltage line,
the third P-channel transistor and the fifth P-channel transistor are configured to turn on based on a negative target voltage from the negative target voltage line,
the sixth N-channel transistor is configured to turn on based on the positive target voltage from the positive target voltage line, and
the output voltage line is configured to have the negative target voltage applied from the negative target voltage line.

12. The level shifter of claim 10, wherein
the first N-channel transistor is configured to turn on based on the input voltage having the first voltage level,
the fourth P-channel transistor is configured to turn on based on a negative target voltage from the negative target voltage line,
the third N-channel transistor and the fifth N-channel transistor are configured to turn on based on a positive target voltage from the above positive target voltage line,
the sixth P-channel transistor is configured to turn on based on the negative target voltage from the negative target voltage line, and
the output voltage line is configured to have the positive target voltage applied from the positive target voltage line.

13. A memory device comprising:
an input/output circuit configured to transmit and receive data, the input/output circuit including a level shifter, wherein
the level shifter includes
a mid voltage output circuit configured to output a mid voltage based on an input voltage swinging between a first voltage level and a second voltage level,
a feedback circuit configured to output a feedback voltage and an output voltage that swings between a positive target voltage level and a negative target voltage level, the output of the feedback circuit based on a positive target voltage, a negative target voltage and the mid voltage,
a pull-up voltage control circuit configured to output at least one of a first voltage or the positive target voltage to the mid voltage output circuit, the output of the pull-up voltage control circuit based on the feedback voltage, and
a pull-down voltage control circuit configured to output at least one of a second voltage or the negative target voltage to the mid voltage output circuit, the output of the pull-down voltage control circuit based on the feedback voltage.

14. The memory device of claim 13, wherein the mid voltage output circuit comprises:
a pull-up circuit configured to output the positive target voltage as the mid voltage based on the input voltage; and
a pull-down circuit configured to output the negative target voltage as the mid voltage based on the input voltage.

15. The memory device of claim 14, wherein,
in response to the level of the input voltage being the first voltage level, a connection between the pull-up circuit and a node to which the mid voltage is applied is electrically opened, and
in response to the level of the input voltage being the second voltage level, a connection between the pull-down circuit and the node to which the mid voltage is applied is electrically opened.

16. The memory device of claim 13, wherein the feedback circuit determines the feedback voltage based on a voltage level of the input voltage.

17. The memory device of claim 14, wherein the pull-up voltage control circuit and the pull-down voltage control circuit are configured to complementarily output a corresponding one of the positive target voltage and the negative target voltage to the mid voltage output circuit according to the feedback voltage and based on a voltage level of the input voltage.

18. The memory device of claim 14, wherein
the pull-up voltage control circuit is configured to output the positive target voltage to the mid voltage output circuit, based on the feedback voltage and on the input voltage having the second voltage level, and
the pull-down voltage control circuit is configured to output the negative target voltage to the mid voltage output circuit, based on the feedback voltage and on the input voltage having the first voltage level.

19. The memory device of claim 14, wherein
the pull-up voltage control circuit is configured to output the positive target voltage to the mid voltage output circuit, based on the feedback voltage and on the input voltage having the second voltage level,
the mid voltage output circuit is configured to output the positive target voltage as the mid voltage based on the input voltage having the second voltage level, and
the feedback circuit is configured to output an output voltage having a negative target voltage level based on the positive target voltage.

20. The memory device of claim 14, wherein
the pull-down voltage control circuit is configured to output the negative target voltage to the mid voltage output circuit, based on the feedback voltage and on the input voltage having the first voltage level,
the mid voltage output circuit is configured to output the negative target voltage as the mid voltage based on the input voltage having the first voltage level, and
the feedback circuit is configured to output an output voltage having a positive target voltage level based on the negative target voltage.
